(19) United States
(12) Patent Application Publication
(10) Pub. No.: US 2008/0185704 A1
(43) Pub. Date: Aug. 7, 2008

(54) Carrier plate structure havign a chip embedded therein and the manufacturing method of the same

(75) Inventors: Shih-Ping Hsu, Hsinchu (TW); Chung-Cheng Lien, Hsinchu (TW); Kan-Jung Chia, Hsinchu (TW); Shang-Wei Chen, Hsinchu (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/701,409

(22) Filed: Feb. 2, 2007

(51) Int. Cl. H01L 21/00; H01L 23/48

(52) U.S. Cl. 257/690; 438/119; 257/E23.01; 257/E21.001

(57) ABSTRACT

A carrier plate structure having a chip embedded therein, comprises an aluminum plate having plural through-holes extending from the upper surface to the lower surface of the aluminum plate, a cavity therein, and an aluminum oxide layer formed on the surface of the aluminum plate; a chip embedded in the cavity with an active surface having plural electrode pads set thereon; and at least one build-up structure mounted on the surface of the aluminum plate and the active surface of the chip, wherein the build-up structure comprises at least one conductive structure to electrically connecting to the electrode pad. Besides, a method of manufacturing a carrier plate structure having a chip embedded therein is disclosed.

### BACKGROUND OF THE INVENTION

1. Field of the Invention

The present invention relates to a carrier plate structure having a chip embedded therein and the manufacturing method of the same, more particularly, to a carrier plate structure having a chip embedded therein with low cost and suitable for the integration of electronic devices, and the manufacturing method of the same.

2. Description of Related Art

In the development of electronics, the design trend of electronic devices is towards multifunction and high-performance. Thus, high-density integration and miniaturization are necessary for a semiconductor package structure. On the reason aforementioned, the double layer circuit boards providing active components, passive components, and circuit connection, are being replaced by the multilayer circuit boards. The area of circuit layout on the circuit board is increased within a restricted space by interlayer connection to meet with the requirement of high-density integration.

In the general process of fabricating a semiconductor device, a wafer maker fabricates a wafer first, according to the customer's requirements, and an IC package substrate maker fabricates an IC package substrate for a semiconductor device, e.g. a package substrate; and then a semiconductor package maker performs chip mounting, wire bounding, molding, solder ball implanting on the IC package substrate; finally, a semiconductor device of the electrical performance required by a customer is accomplished. Since the above process involves various makers, the process is complex and the interface integration is not always appropriate. Furthermore, if a customer desires to change the function design, the transformation and the integration are too complex so as to limit the efficiency and the change flexibility.

In the conventional semiconductor device structure, a semiconductor chip is attached on top of a substrate and then processed in wire bonding or a chip is connected to a substrate by a flip chip package, and then forming solder balls on the back surface of the substrate to electrically connect with the outer electronic devices. Although more connecting ends are provided, the performance of electronic devices cannot be enhanced but is in fact restricted, owing to the over-long path of circuits and then high resistance for high frequency operation. Furthermore, the repeated interlayer connection of the conventional package aggravates the complexity of the process.

Hence, significant research focuses on embedding a chip in a package substrate. The chip of the package substrate electrically connects to an outer electronic device to shorten signal pathway, inhibit signal loss, reduce signal distortion, and enhance performance in high-speed operation.

As shown in FIG. 1, a carrier plate structure 100 having a chip embedded therein comprises: a carrier plate 101, a chip 102, plural electrode pads 103, and a build-up structure 106. A cavity is formed in the carrier plate 101 and the chip 102 having a plurality of electrode pads formed thereon is disposed in the cavity. The electrode pads 103 have been formed on the surface of the chip 102. The build-up structure 106 is formed on the surfaces of the carrier plate 101 and the chip 102. The build-up structure 106 comprises at least one conductive circuit 104 electrically connecting to the carrier plate 101 and the electrode pads 103 of the chip 102.

In general, the material of the carrier plate 101 (shown in FIG. 1) is ceramic material (e.g. aluminum oxide, Young's modulus is 380 Gpa). Owing to the excellent heat dissipation and mechanical characteristics, the bend of the carrier plate structure is inhibited, the fine arrangement of circuit layout is realized easily, and the size stability is high. However, the cost of high-temperature sintering to fabricate a large-size ceramic plate is very high. Thereby, if the ceramic material is formed as the carrier plate of a carrier plate structure having a chip embedded therein by high-temperature sintering, the cost is unacceptably high.

Therefore, it is desirable to reduce the cost of fabricating a carrier plate structure having a chip embedded therein, and simplify the process.

### SUMMARY OF THE INVENTION

In order to obviate the aforementioned problems, the present invention provides a carrier plate structure having a chip embedded therein, comprising: an aluminum plate having an upper surface, a lower surface, plural through holes extending from the upper surface to the lower surface of the aluminum plate, a cavity therein, and an aluminum oxide layer formed on the upper surface, the lower surface of the aluminum plate, and the inner walls of the through holes; a chip embedded in the cavity with an active surface having plural electrode pads set thereon; a metal layer disposed on the inner walls of the through holes, wherein the metal layer electrically connects to plural electrical conductive pads disposed on the upper and the lower surfaces of the aluminum plate; and at least one build-up structure mounted on the surface of the aluminum plate and the active surface of the chip, wherein the build-up structure comprises plural conductive structures electrically connecting to the electrode pads and the electrical conductive pads.

Since the aluminum oxide layer formed on the surface of the aluminum plate of the carrier plate structure having a chip embedded therein is the material of metal/ceramic composites having ceramic rigidity and metal toughness, the bend caused from the asymmetric build-up structure is inhibited in usage of the aforementioned plate as the core-substrate of a carrier plate structure having a chip embedded therein.

In addition, the metal layer on the inner walls of the through holes of the carrier plate structure having a chip embedded therein of the present invention is a continuous metal layer connecting the upper surface to the lower surface of the aluminum plate, and functions as a conductive channel connecting the upper surface to the lower surface of the aluminum plate. Accordingly, in assembling an electronic device with the carrier plate structure, the electronic device can electrically connect to the circuit or the build-up structure on the other surface of the aluminum plate through the metal layer without requiring additional circuits.

The thickness of the aluminum oxide layer of the aluminum plate of the carrier plate structure having a chip embedded therein of the present invention is not limited. The thickness of the aluminum oxide layer depends on the requirement of rigidity and toughness of the carrier plate structure. The method for controlling the thickness of the aluminum oxide layer is also not limited, and various oxidation and conditions can achieve the goal.

The material of the aluminum plate of the carrier plate structure having a chip embedded therein of the present invention can be aluminum oxide or an alloy thereof. Preferably, the material of the aluminum plate is an aluminum oxide alloy. The method for forming the aluminum oxide layer on the surface of the aluminum plate can be any oxidation method. Preferably, the method for forming the aluminum oxide layer is anodic oxidation.

In addition, the width of the through hole of the aluminum plate of the carrier plate structure having a chip embedded therein of the present invention is not limited. The width of the through hole depends on the requirement of electrical performance or the thickness of the carrier plate structure. The method for controlling the width of the through hole is also not limited, and various methods and conditions can achieve the goal.

The metal layer in the through holes of the carrier plate structure having a chip embedded therein of the present invention connects the upper surface to the lower surface of the aluminum plate, and the thickness of the metal layer is not limited. Preferably, the metal layer is formed on the inner walls of the through holes and the through holes are hollow; the metal layer is formed on the inner walls of the through holes and the through holes are filled with a resin to the full; or the metal layer is formed on the inner walls of the through holes and the through holes are completely filled with the metal layer.

The carrier plate structure having a chip embedded therein of the present invention further comprises plural electrical conductive pads disposed on the upper and the lower surfaces of the aluminum plate and electrically connecting to the metal layer.

The carrier plate structure having a chip embedded therein of the present invention further comprises at least one electronic device disposed on the electrical conductive pads on the surface of the aluminum plate without the build-up structure, and electrically connecting to the metal layer.

The material of the electrode pads of the carrier plate structure having a chip embedded therein of the present invention is not limited and can be any metal. Preferably, the material of the electrode pads is aluminum or copper.

In the carrier plate structure having a chip embedded therein of the present invention, a material which can fix the chip in the cavity of the aluminum plate can be disposed between the chip and the aluminum plate. The material for fixing the chip in the cavity of the aluminum plate is not limited. Preferably, the material fixing the chip in the cavity of the aluminum plate is an epoxy resin or a dielectric material.

The build-up structure of the carrier plate structure having a chip embedded therein of the present invention comprises a dielectric layer, a circuit layer disposed on the dielectric layer, and at least one the conductive structure passing through the dielectric layer to electrically connect the circuit layer to another circuit layer under the dielectric layer, the electrode pads, or the electrical conductive pads.

The material of the dielectric layer of the build-up structure is not limited. Preferably, the material of the dielectric layer is selected from the group consisting of ABF (Ajinomoto Build-up Film), BT (Bismaleimide triazine), BCB (Benzocyclo-buthene), LCP (Liquid Crystal Polymer), PI (Poly-imide), PPE (Poly(phenylene ether)), PTFE (Poly (tetra-fluoroethylene)) or Aramide, epoxy resin, and fiber glass. The material of the build-up structure and the conductive structure is not limited. Preferably, the material of the build-up structure and the conductive structure is copper, tin, nickel, chromium, titanium, a copper/chromium alloy, or a tin/lead alloy.

The carrier plate structure having a chip embedded therein further comprises a solder mask formed on the surface of the build-up structure as an insulated layer. Plural openings are formed in the solder mask to expose the electrical conductive pads on the surface of the build-up structure. Plural solder bumps electrically connecting to the build-up structure are disposed in the openings of the solder mask.

A seed layer is further formed between the build-up structure and the dielectric layer or the conductive structures and the solder bumps. The seed layer mainly functions as a current pathway needed for electroplating. The material of the seed layer can be selected from the group consisting of copper, tin, nickel, chromium, titanium, a copper/chromium alloy, and a tin/lead alloy. Alternatively, the material of the seed layer can be conductive polymer. The conductive polymer can be selected from the group consisting of polyacetylene, polyaniline, and organo-sulfur polymer.

Furthermore, the present invention also provides a method for manufacturing a carrier plate structure having a chip embedded therein, comprising the following steps: (A) providing an aluminum plate having an upper surface, a lower surface, plural through holes extending from the upper surface to the lower surface of the aluminum plate; (B) performing the oxidation of the aluminum plate to form an aluminum oxide layer on the upper surface, the lower surface of the aluminum plate, and the inner walls of the through holes; (C) forming a continuous metal layer on the inner walls of the through holes, wherein the metal layer connects the upper surface of the aluminum plate to the lower surface of the aluminum plate, and forming electrical conductive pads on both ends of the metal layer; (D) forming a cavity in the aluminum plate; (E) embedding and fixing a chip having plural electrode pads on the active surface of the chip in the cavity of the aluminum plate; and (F) forming at least one build-up structure on the surface of the aluminum plate and the active surface of the chip, wherein the build-up structure comprises at least one conductive structure corresponding to the electrode pad and electrically connecting to the electrode pad and the electrical conductive pad.

Since the aluminum oxide layer, formed on the surface of the aluminum plate of the carrier plate structure having a chip embedded therein by oxidation of the surface of the aluminum plate, is a metal/ceramic composition having ceramic rigidity and metal toughness, the bend caused from the asymmetric build-up structure is inhibited in usage of the aforementioned plate as the core-substrate of a carrier plate structure having a chip embedded therein.

In addition, the metal layer on the inner walls of the through holes of the carrier plate structure having a chip embedded therein of the present invention is a continuous metal layer connecting the upper surface to the lower surface of the aluminum plate, and functions as a conductive channel electrically connecting the upper surface to the lower surface of the aluminum plate. Accordingly, in assembling an electronic device and the carrier plate structure, the electronic device can electrically connect to the circuit or the build-up structure on the other surface of the aluminum plate through the metal layer without requiring additional circuits.

The thickness of the aluminum oxide layer of the aluminum plate of the carrier plate structure having a chip embedded therein of the present invention is not limited. The thickness of the aluminum oxide layer depends on the requirement of rigidity and toughness of the carrier plate structure. The method for controlling the thickness of the aluminum oxide layer is also not limited, and various oxidations and conditions can achieve the goal.

In the method for manufacturing a carrier plate structure having a chip embedded therein of the present invention, the material of the aluminum plate of the step (A) can be aluminum or an alloy thereof. Preferably, the material of the aluminum plate is an aluminum oxide alloy. In the step (B), the method for forming the aluminum oxide layer on the surface of the aluminum plate can be any oxidation method. Preferably, the method for forming the aluminum oxide layer is anodic oxidation.

Furthermore, in the method for manufacturing a carrier plate structure having a chip embedded therein of the present invention, the width of the through hole of the aluminum plate of the carrier plate structure having a chip embedded therein of the present invention is not limited. The width of the through hole depends on the requirement of electrical performance and the thickness of the carrier plate structure. The method for controlling the width of the through hole is also not limited, and various methods and conditions can achieve the goal.

In the method for manufacturing a carrier plate structure having a chip embedded therein of the present invention, the method for forming the metal layer of the step (C) is not limited. Preferably, the method for forming the metal layer is electroplating, or filling the through holes with the metal.

In the method for manufacturing a carrier plate structure having a chip embedded therein of the present invention, after forming the metal layer on the inner walls of the through holes in the step (C), the through holes can be completely filled selectively with a resin and then plural electrical conductive pads electrically connecting to the metal layer are formed on the upper and the lower surfaces of the aluminum plate.

The method for manufacturing a carrier plate structure having a chip embedded therein further comprises a step (G), disposing an electronic device on the electrical conductive pads on the surface of the aluminum plate without the build-up structure, wherein the electronic device electrically connects to the metal layer.

In the method for manufacturing a carrier plate structure having a chip embedded therein of the present invention, the material of the electrode pads is not limited and can be any metal. Preferably, the material of the electrode pads is aluminum or copper.

In the method for manufacturing a carrier plate structure having a chip embedded therein of the present invention, after the chip is embedded in the cavity of the aluminum plate, a material which can fix the chip in the cavity of the aluminum plate can be disposed between the chip and the aluminum plate. Preferably, the material fixing the chip in the cavity of the aluminum plate is an epoxy resin or a dielectric material.

In the method for manufacturing a carrier plate structure having a chip embedded therein of the present invention, the process of manufacturing the build-up structure comprises the following steps: forming a dielectric layer on the surface of the aluminum plate and the active surface of the chip, and forming plural vias corresponding to the electrode pads on the chip and the electrical conductive pads on the surface of the aluminum plate in the dielectric layer; forming a seed layer on the dielectric layer and in the vias of the dielectric layer, forming a resistive layer on the surface of the seed layer, and forming plural openings in the resistive layer by exposure and development, wherein at least one of the openings of the resistive layer corresponds to the electrode pad on the chip; electroplating a plated metal layer in the plural openings of the resistive layer, and removing the resistive layer and the seed layer covered by the resistive layer, wherein the plated metal layer comprises at least one circuit layer and at least one conductive structure.

According to the process of manufacturing the build-up structure, before forming the patterned resistive layer, the seed layer is formed; and after removing the patterned resistive layer, the seed layer uncovered by the plated metal layer is removed. If the material of the seed layer is selected from the group consisting of copper, tin, nickel, chromium, titanium, a copper/chromium alloy, and a tin/lead alloy (preferably, the material of the seed layer is copper), the method for manufacturing the seed layer is sputtering or electroless plating. Alternatively, if the material of the seed layer is conductive polymer, the method for manufacturing the seed layer is spin coating, ink-jet printing, screen printing, or imprinting. The material of the conductive polymer is selected from the group consisting of polyacetylene, polyaniline, and organo-sulfur polymer.

In the method for manufacturing a carrier plate structure having a chip embedded therein of the present invention, the material of the dielectric layer of the build-up structure is not limited. Preferably, the material of the dielectric layer is selected from the group consisting of ABF (Ajinomoto Build-up Film), BT (Bismaleimide triazine), BCB (Benzocyclo-buthene), LCP (Liquid Crystal Polymer), PI (Poly-imide), PPE (Poly(phenylene ether)), PTFE (Poly (tetra-fluoroethylene)) or aramide, epoxy resin, and fiber glass.

In the step of manufacturing the build-up structure, the material of the plated metal layer is not limited. Preferably, the material of the plated metal layer is copper, tin, nickel, chromium, palladium, titanium, tin/lead alloy, or an alloy thereof. More preferably, the material of the plated metal layer is copper.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a conventional method of manufacturing a carrier plate structure having a chip embedded therein;

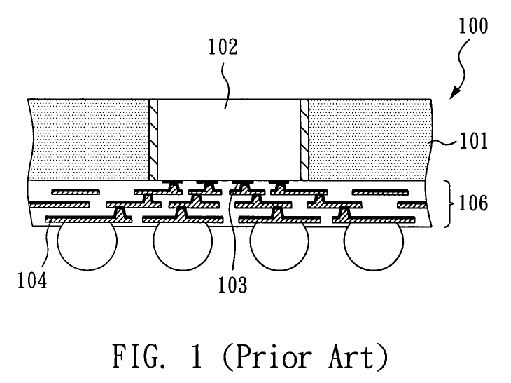

FIGS. 2(a) to 2(f) are cross-section views of manufacturing a carrier plate structure having a chip embedded therein of a preferred embodiment;

FIGS. 3(a) to 3(c) are cross-section views of manufacturing a build-up structure of a preferred embodiment; and

FIG. 4 is a cross-section view of the manufacturing method of another preferred embodiment.

### DETAILED DESCRIPTION OF THE PREFERRED EMBODIMENT

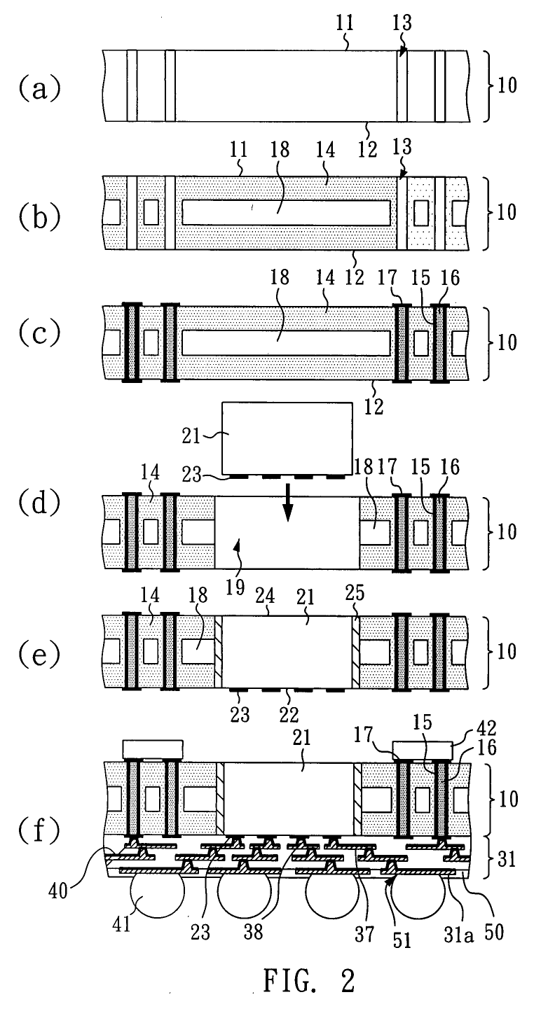

With reference to FIGS. 2(a) to 2(f), there are shown cross-section views of manufacturing a carrier plate structure having a chip embedded therein of the present embodiment.

An aluminum plate 10 (Young's modulus=70 Gpa) is provided first, and then plural through holes 13 are formed in the aluminum plate 10 by machine-drilling. The through holes 13 extend from the upper surface 11 to the lower surface 12 of the aluminum plate 10, as shown in FIG. 2(a).

The aluminum plate 10 is placed in an electrolysis tank to perform the oxidation reaction. Then an aluminum oxide layer 14 is formed on the surface of the aluminum plate 10, and the remaining aluminum plate 10 is referred to as an aluminum layer 18, as shown in FIG. 2(b).

The aluminum plate 10 of the present embodiment is disposed in an electrolysis tank having oxalic acid solution or sulfuric acid solution as an electrolyte therein to perform the anodic oxidation. The thickness of the aluminum oxide layer 14 depends on the anodic oxidation time. The Young's modulus of the oxidized aluminum plate is 400 Gpa. Accordingly, the present embodiment can simultaneously accomplish the aluminum layer (metal material) and the aluminum oxide layer (ceramic material) of the carrier plate structure without requiring additional steps, e.g. no heat pressing or sintering is required. In addition, the connection between the aluminum layer 18 and the aluminum oxide layer 14 is intense, and thereby the aluminum plate of the present embodiment presents the metal toughness and the ceramic rigidity.

Subsequently, as shown in FIG. 2(c), after forming the aluminum oxide layer 14 with ceramic rigidity on the upper surface 11, the lower surface 12 of the aluminum plate 10, and the inner walls of the through holes 13, a metal layer 15 is electroplated on the inner walls of the through holes 13. The metal layer 15 is a continuous metal layer connecting the upper surface 11 of the aluminum plate 10 to the lower surface 12 of the aluminum plate 10. The metal layer of the present embodiment is copper. Then, the through holes 13 are completely filled with a resin, and electrical conductive pads 17 are formed on each end of the metal layer 15 connecting the upper surface 11 to the lower surface 12 of the aluminum plate 10. The electrical conductive pads 17 connect the metal layer 15 to an outer device, and the electrical conductive pads 17 electrically connect to the metal layer 15. The electrical conductive pads are produced by forming a patterned resistive layer (not shown) on the upper and the lower surfaces of the aluminum plate 10, electroplating or depositing a copper layer on the surface uncovered by the resistive layer, and removing the patterned resistive layer. Since the manufacturing method of the electrical conductive pad 17 is a conventional method, the present embodiment does not show figures of the manufacturing method of the electrical conductive pad.

Subsequently, as shown in FIG. 2(d), the aluminum plate 10 is cut by a router to form a cavity 19, and then a chip 21 is embedded in the cavity 19 of the aluminum plate 10. There are plural electrode pads 23 on the active surface 22 of the chip 21, and the material of the electrode pads 23 is copper. The vacant space between the aluminum plate 10 and the chip 21 is filled with an epoxy resin 25 to fix the chip 21 in the cavity 19 of the aluminum plate 10, as shown in FIG. 2(e). In the present embodiment, the active surface 22 of the chip 21 is exposed for good heat dissipation of the chip 21.

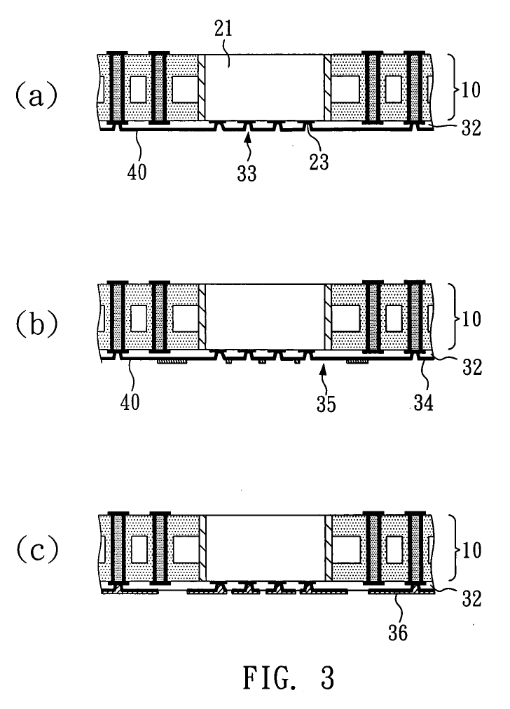

After the above steps, a build-up structure 31 is formed on the surface of the aluminum plate 10 and the active surface 22 of the chip 21, as shown in FIG. 2(f). The manufacturing method of the build-up structure 31 is shown in FIGS. 3 (a) to 3(c). A dielectric layer 32 is formed on the lower surface of the aluminum plate 10 and the active surface 22 of the chip 21 first. The material of the dielectric layer 32 is selected from the group consisting of ABF (Ajinomoto Build-up Film), BT (Bismaleimide triazine), BCB (Benzocyclo-buthene), LCP (Liquid Crystal Polymer), PI (Poly-imide), PPE (Poly(phenylene ether)), PTFE (Poly(tetra-fluoroethylene), aramide, epoxy resin, and fiber glass. The material of the dielectric layer 32 of the present embodiment is ABF (Ajinomoto Build-up Film). Next, plural vias 33 are formed in the dielectric layer 32 by laser-drilling or exposure and development. At least one of the vias 33 corresponds to the electrode pad 23 of the chip 21, as shown in FIG. 3(a). If the vias 33 of the dielectric layer 32 are formed by laser-drilling, the smear in the vias 33 of the dielectric layer 32 has to be removed by a de-smearing process. Then, a seed layer 40 is formed on the surface of the dielectric layer 32 and the vias 33, and a resistive layer 34 is formed on the seed layer 40. Plural openings 35 are formed in the resistive layer 34 by exposure and development, and at least one of the openings 35 of the resistive layer 34 corresponds to the electrode pad 23 of the chip 21, as shown in FIG. 3(b). Finally, as shown in FIG. 3(c), a plated metal layer 36 is electroplated in the plural openings 35 of the resistive layer 34, and the resistive layer 34 and the seed layer 40 covered by the resistive layer 34 are removed. The build-up structure 31 shown in FIG. 2(f) is fabricated by a build-up process. The plated metal layer 36 comprises the circuit layer 37 and the conductive structures 38 connecting to the electrode pads 23 of the chip 21.

Finally, as shown in FIG. 2(f), a solder mask 50 is formed on the surface of the build-up structure 31 as an insulated layer. Openings 51 are formed in the solder mask 50 to expose the electrical conductive pads 31a on the surface of the build-up structure 31. Plural solder bumps 41 are disposed in the openings 51 of the solder mask 50, and electrically connect to the build-up structure 31. An electronic device 42 is disposed on the surface of the aluminum plate 10 to connect to the electrical conductive pads 17 and the metal layer 15. Thereby, the carrier plate structure having a chip embedded therein of the present embodiment is accomplished.

In assembling the aluminum plate 10 and the electronic device 42 of the present embodiment, the metal layer 15 formed on the through hole 13 in the aluminum plate 10 can function as the circuit electrically connecting the upper side to the lower side of the aluminum plate 10, and thereby the aluminum plate 10 electrically connects to the electronic device 42.

### Embodiment 2

The method for manufacturing a carrier plate structure having a chip embedded therein of the present embodiment is similar to that of Embodiment 1. However, the process for fixing the chip in the aluminum plate is different from that in Embodiment 1.

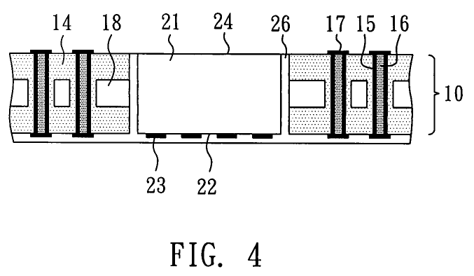

As shown in FIG. 4, after the chip 21 is embedded in the cavity of the aluminum plate 10, a dielectric material 26 is coated on the surface of the aluminum plate 10 and the vacant space between the chip 21 and the aluminum plate 10 is filled with the dielectric material 26 by heat pressing to fix the chip 21 in the cavity of the aluminum plate 10. The dielectric material 26 on the lower surface of the aluminum plate 10 can function as the dielectric layer of the build-up structure to fabricate the build-up structure. Finally, plural solder bumps are formed on the build-up structure and an electronic device is assembled with the aluminum plate 10. Thereby, the carrier plate structure having a chip embedded therein of the present embodiment is accomplished.

Similarly, in assembling the aluminum plate 10 and the electronic device of the present embodiment, the metal layer 15 formed on the through hole 13 in the aluminum plate 10 can function as the circuit electrically connecting the upper side to the lower side of the aluminum plate 10, and thereby the aluminum plate 10 electrically connects to the electronic device.

Although the present invention has been explained in relation to its preferred embodiment, it is to be understood that many other possible modifications and variations can be made without departing from the spirit and scope of the invention as hereinafter claimed.

What is claimed is:

1. A carrier plate structure having a chip embedded therein, comprising:
an aluminum plate having an upper surface, a lower surface, plural through holes extending from the upper surface to the lower surface of the aluminum plate, a cavity therein, and an aluminum oxide layer formed on the upper surface, the lower surface of the aluminum plate, and the inner walls of the through holes;
a chip embedded in the cavity with an active surface having plural electrode pads set thereon;
a metal layer disposed on the inner walls of the through holes, wherein the metal layer electrically connects to plural electrical conductive pads disposed on the upper and the lower surfaces of the aluminum plate; and
at least one build-up structure mounted on the surface of the aluminum plate and the active surface of the chip, wherein the build-up structure comprises plural conductive structures electrically connecting to the electrode pads and the electrical conductive pads.

2. The carrier plate structure having a chip embedded therein as claimed in claim 1, wherein the aluminum oxide layer is formed by anodic oxidation.

3. The carrier plate structure having a chip embedded therein as claimed in claim 1, wherein the electrode pads are aluminum pads or copper pads.

4. The carrier plate structure having a chip embedded therein as claimed in claim 1, wherein the through holes are filled with a resin.

5. The carrier plate structure having a chip embedded therein as claimed in claim 1, wherein the vacant space between the aluminum plate and the chip is filled with an epoxy resin to fix the chip in the cavity of the aluminum plate.

6. The carrier plate structure having a chip embedded therein as claimed in claim 1, wherein the vacant space between the aluminum plate and the chip is filled with a dielectric material to fix the chip in the cavity of the aluminum plate.

7. The carrier plate structure having a chip embedded therein as claimed in claim 1, wherein the build-up structure comprises a dielectric layer, a circuit layer disposed on the dielectric layer, and at least one conductive structure passing through the dielectric layer to connect the circuit layer to another circuit layer under the dielectric layer, the electrode pads or the electrical conductive pads.

8. The carrier plate structure having a chip embedded therein as claimed in claim 1, wherein a solder mask having plural openings to dispose solder bumps electrically connecting to the build-up structure is formed on the surface of the build-up structure.

9. The carrier plate structure having a chip embedded therein as claimed in claim 1, further comprising at least one electronic device disposed on the electrical conductive pads on the aluminum plate without the build-up structure.

10. A method for manufacturing a carrier plate structure having a chip embedded therein, comprising the following steps:
(A) providing an aluminum plate having an upper surface, a lower surface, plural through holes extending from the upper surface to the lower surface of the aluminum plate;
(B) performing the oxidation of the aluminum plate to form an aluminum oxide layer on the upper and the lower surfaces of the aluminum plate, and the inner walls of the through holes;
(C) forming a continuous metal layer on the inner walls of the through holes, wherein the metal layer extends from the upper surface of the aluminum plate to the lower surface of the aluminum plate, and forming electrical conductive pads on both ends of the metal layer;
(D) forming a cavity in the aluminum plate;
(E) embedding and fixing a chip having plural electrode pads on the active surface in the cavity of the aluminum plate; and
(F) forming at least one build-up structure on the surface of the aluminum plate and the active surface of the chip, wherein the build-up structure comprises plural conductive structures corresponding to the electrode pads and the plural electrical conductive structures electrically connect to the electrode pads and the electrical conductive pads.

11. The method for manufacturing a carrier plate structure having a chip embedded therein as claimed in claim 10, wherein in the step (B), the aluminum oxide layer is formed by anodic oxidation.

12. The method for manufacturing a carrier plate structure having a chip embedded therein as claimed in claim 10, wherein in the step (C), after forming the metal layer, the through holes are completely filled with a resin and then the electrical conductive pads are formed.

13. The method for manufacturing a carrier plate structure having a chip embedded therein as claimed in claim 10, wherein in the step (E), the electrode pads are aluminum pads or copper pads.

14. The method for manufacturing a carrier plate structure having a chip embedded therein as claimed in claim 10, wherein in the step (E), the vacant space between the aluminum plate and the chip is filled with an epoxy resin to fix the chip in the cavity of the aluminum plate.

15. The method for manufacturing a carrier plate structure having a chip embedded therein as claimed in claim 10, wherein in the step (E), the vacant space between the aluminum plate and the chip is filled with a dielectric material to fix the chip in the cavity of the aluminum plate.

16. The method for manufacturing a carrier plate structure having a chip embedded therein as claimed in claim 10, wherein the process of forming at least one build-up structure of the step (F) comprises the following steps:
forming a dielectric layer on the surface of the aluminum plate and the active surface of the chip and forming plural vias corresponding to the electrode pads on the chip and the electrical conductive pads on the surface of the aluminum plate in the dielectric layer;
forming a seed layer on the surface of the dielectric layer and in the vias of the dielectric layer, forming a resistive layer on the surface of the seed layer, and forming plural openings in the resistive layer, wherein at least one opening of the resistive layer corresponds to the electrode pad on the chip;
electroplating a plated metal layer in the plural openings of the resistive layer; and
removing the resistive layer and the seed layer covered by the resistive layer, wherein the plated metal layer comprises at least one circuit layer and at least one conductive structure.

17. The method for manufacturing a carrier plate structure having a chip embedded therein as claimed in claim 10, wherein the plated metal layer is copper, tin, nickel, chromium, palladium, titanium, tin/lead, or an alloy thereof.

18. The method for manufacturing a carrier plate structure having a chip embedded therein as claimed in claim 10, further comprising a step (G), disposing an electronic device on the electrical conductive pads on the surface of the aluminum plate without the build-up structure, wherein the electronic device electrically connects to the metal layer.
